(19) United States
(12) Patent Application Publication
(10) Pub. No.: US 2008/0251814 A1
(43) Pub. Date: Oct. 16, 2008

(54) HETERO-BONDED SEMICONDUCTOR-ON-INSULATOR SUBSTRATE WITH AN UNPINNING DIELECTRIC LAYER

(75) Inventor: Byoung H. Lee, Austin, TX (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/735,724

(22) Filed: Apr. 16, 2007

(51) Int. Cl. H01L 29/737; H01L 21/44

(52) U.S. Cl. 257/200; 438/311; 257/E29.188; 257/E21.476

(57) ABSTRACT

A hetero-bonded SOI substrate comprises a stack of a semiconductor handle substrate, an isolation insulator layer, a depinning dielectric layer, and a top non-silicon semiconductor layer. The depinning layer abuts both the top non-silicon semiconductor layer and the isolation insulator layer and relaxes Fermi level pinning in the top non-silicon semiconductor layer. The top non-silicon semiconductor layer may be a III-V compound semiconductor layer such as GaAs and the depinning dielectric layer may be a (GdₓGa₁₋ₓ)₂O₃ layer. The interface defect density may be reduced below 5.0×10¹¹ cm⁻² eV⁻¹.

### FIELD OF THE INVENTION

The present invention relates to a semiconductor structure, and particularly to a hetero-bonded semiconductor-on-insulator substrate with an unpinning dielectric layer and methods of manufacturing the same.

### BACKGROUND OF THE INVENTION

A hetero-bonded semiconductor-on-insulator (SOI) substrate has different compositions between a top semiconductor layer and a semiconductor handle substrate. For example, the semiconductor handle substrate may comprise silicon and the top semiconductor layer may comprise a III-V semiconductor material or a II-VI semiconductor material. Typically, the material for the semiconductor handle substrate is selected for efficient and easy handling of the hetero-bonded SOI substrate while the material for the top semiconductor layer is selected for optimal device performance.

FIG. 1 shows an exemplary prior art hetero-bonded SOI substrate, which comprises a semiconductor handle substrate 10, an isolation insulator layer 12, and a top semiconductor layer 22. The semiconductor handle substrate 10 comprises silicon and the isolation insulator layer 12 comprises silicon oxide formed by oxidation of the semiconductor handle substrate 10. The top semiconductor layer 22 comprises GaAs. The exemplary prior art hetero-bonded SOI substrate may be formed by implanting a GaAs substrate with hydrogen followed by bonding of the GaAs substrate to the isolation insulator layer 12 formed on the semiconductor handle substrate 10, and subsequently cleaving the bonded structure along a hydrogen implanted layer. Alternatively, the GaAs substrate may be polished to a desired thickness instead of employing hydrogen implantation.

In general, when the periodic structure of a crystal lattice is terminated at a surface, surface-specific states, or electron states with a larger amplitude at the surface compared to the bulk, are formed. The surface states have no equivalent counterparts in the band structure of an ideal bulk crystal of infinite size. Surface-specific states may be true surface states in which the amplitude of the wave functions has a peak near the surface and decays away from the surface in either direction. Alternatively, surface-specific states may be surface resonant states that have enhanced amplitudes at the surface but are coupled to bulk states. Surface states in the band gap of a semiconductor material are known to “pin” the Fermi level position of the semiconductor material at the surface.

One of the problems of the prior art hetero-bonded SOI substrate is a high density of interface defect states, which are surface-states. The interface defect density of the prior art hetero-bonded SOI substrate far exceeds 5.0×10¹¹ cm⁻² eV⁻¹. Referring to FIG. 1B, the band structure of the exemplary prior art structure shows the valence band energy level Eᵥ and the conduction band energy level E_{c} within various portions of the hetero-bonded SOI substrate. Interface defect states of high density are formed at the interface between the top semiconductor layer 22 comprising GaAs and the isolation insulator layer 12 comprising silicon oxide. The peak of the amplitude of their wave functions is located within the GaAs top semiconductor layer 22. The interface defect states pin the Fermi level within the GaAs top semiconductor layer 22 and degrades the mobility of electrical carriers, i.e., electrons or holes. In other words, the interface state density is high enough to adversely impact the carrier mobility.

In many other hetero-bonded SOI substrate structures having a different composition, the presence of high density interface defect states causes severe mobility degradation in a top semiconductor layer as the thickness of the top semiconductor layer becomes thin enough, i.e., below 50 nm. In ultra-thin top semiconductor layers, carrier mobility degradation due to the high density interface defects may become a dominant factor in limiting device performance.

Therefore, there exists a need for a hetero-bonded semiconductor-on-insulator substrate structure having a low density of surface specific states and methods of manufacturing the same.

In particular, there exists a need for a hetero-bonded semiconductor-on-insulator substrate structure with a GaAs top semiconductor layer having a low interface defect density and methods of manufacturing the same.

### SUMMARY OF THE INVENTION

The present invention addresses the needs described above by providing a hetero-bonded semiconductor-on-insulator (SOI) substrate having a depinning dielectric layer between an isolation insulator layer and a top semiconductor layer.

Specifically, the hetero-bonded SOI substrate comprises a stack of a semiconductor handle substrate, an isolation insulator layer, a depinning dielectric layer, and a top non-silicon semiconductor layer. The depinning dielectric layer abuts both the top non-silicon semiconductor layer and the isolation insulator layer and relaxes Fermi level pinning in the top non-silicon semiconductor layer. The top non-silicon semiconductor layer may be a III-V compound semiconductor layer such as GaAs and the depinning dielectric layer may be a (GdₓGa₁₋ₓ)₂O₃ layer. The interface defect density may be reduced below 5.0×10¹¹ cm⁻² eV⁻¹.

According to one aspect of the present invention, a hetero-bonded semiconductor-on-insulator substrate comprises:

a semiconductor handle substrate;

an isolation insulator layer abutting the semiconductor handle substrate;

a depinning dielectric layer abutting the isolation insulator layer; and

a top non-silicon semiconductor layer, wherein the depinning dielectric layer relaxes Fermi level pinning in the top non-silicon semiconductor layer.

According to another aspect of the present invention, a method of forming a hetero-bonded semiconductor-on-insulator substrate comprises:

providing a semiconductor handle substrate;

forming an isolation insulator layer on the semiconductor handle substrate;

providing a non-silicon semiconductor substrate having a hydrogen implanted layer;

forming a depinning dielectric layer on a structure selected from the semiconductor handle substrate and the non-silicon semiconductor substrate;

bonding the semiconductor handle substrate and the non-silicon semiconductor substrate, wherein the depinning dielectric layer abuts a bonding surface; and

cleaving the non-silicon semiconductor substrate along the hydrogen implanted layer.

### BRIEF DESCRIPTION OF THE DRAWINGS

FIG. 1A is an exemplary prior art hetero-bonded semiconductor-on-insulator (SOI) substrate.

FIG. 1B shows the band structure of the exemplary prior art hetero-bonded SOI substrate in FIG. 1A.

FIG. 2A is an exemplary hetero-bonded semiconductor-on-insulator (SOI) substrate according to the present invention.

FIG. 2B shows the band structure of the exemplary hetero-bonded SOI substrate in FIG. 2A according to the present invention.

FIG. 3 is a diagram illustrating a first method of forming a hetero-bonded SOT substrate according to the present invention.

FIG. 4 is a diagram illustrating a second method of forming a hetero-bonded SOI substrate according to the present invention.

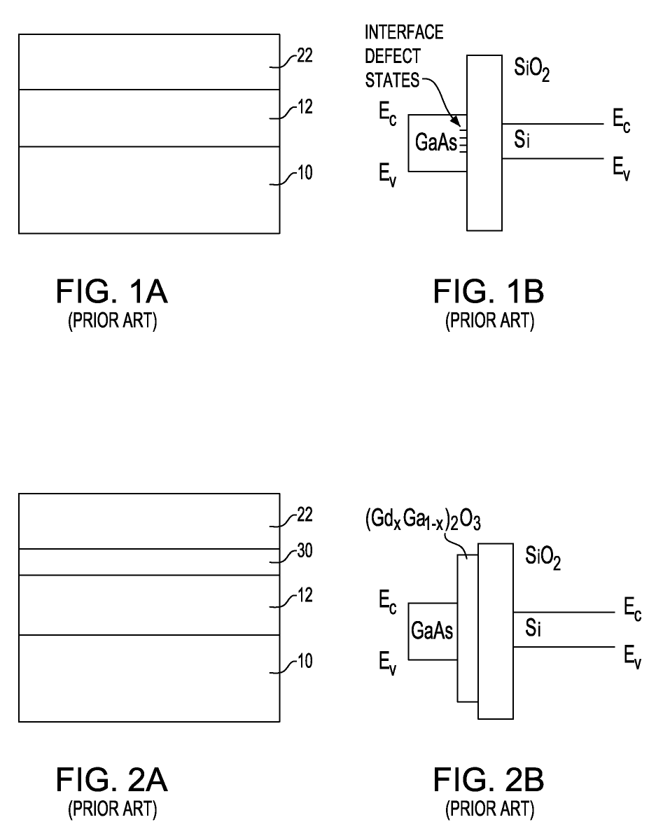

### DETAILED DESCRIPTION OF THE INVENTION

As stated above, the present invention relates to a hetero-bonded semiconductor-on-insulator (SOT) substrate with an unpinning dielectric layer and methods of manufacturing the same, which are now described in detail with accompanying figures. It is noted that like and corresponding elements are referred to by like reference numerals.

Referring to FIG. 2A, an exemplary hetero-bonded SOI substrate comprises a semiconductor handle substrate 10, an isolation insulator layer 12, a depinning dielectric layer 30, and a top non-silicon semiconductor layer 22. The depinning dielectric layer 30 abuts both the isolation insulator layer 12 and the top non-silicon semiconductor layer 22. The isolation insulator layer 12 abuts the semiconductor handle substrate 10.

The semiconductor handle substrate 10 may comprise any semiconductor material including, but not limited to, silicon, silicon germanium alloy, silicon carbon alloy, silicon germanium carbon alloy, GaAs, InAs, InP, and other III-V or II-VI compound semiconductors. The semiconductor handle substrate 10 may be single crystalline, polycrystalline, or amorphous. For example, the semiconductor handle substrate 10 may comprise silicon.

The top non-silicon semiconductor layer 22 may comprise any semiconductor material other than pure silicon, including, but not limited to, silicon germanium alloy, silicon carbon alloy, silicon germanium carbon alloy, GaAs, InAs, InP, and other III-V or II-VI compound semiconductors. The top non-silicon semiconductor layer 22 is preferably single crystalline. Hybrid crystal orientations, i.e., multiple crystalline orientations, for the top non-silicon semiconductor layer 22 are explicitly contemplated herein. The semiconductor handle substrate 10 and the top non-silicon semiconductor layer 22 comprise different semiconductor material to form the “hetero-bonded” SOI substrate. For example, the top non-silicon semiconductor layer 22 may comprise a III-V compound semiconductor layer. In one exemplary embodiment, the III-V compound semiconductor layer may be a GaAs layer.

The isolation insulation layer 12 is a dielectric layer such as an oxide or a nitride. The isolation insulation layer 12 may be derived from the material of the semiconductor handle substrate 10. For example, if the semiconductor handle substrate 10 comprises silicon, the isolation insulation layer 12 may comprise silicon oxide or silicon nitride. In the exemplary embodiment, the isolation insulation layer 12 is silicon oxide. The isolation insulation layer 12 has a thickness in the range from about 10 nm to about 300 nm, and preferably in the range from about 50 nm to about 150 nm.

The depinning dielectric layer 30 relaxes Fermi level pinning in the top non-silicon semiconductor layer 22. The depinning dielectric layer 30 has a thickness in the range from about 0.3 nm to about 100 nm, and preferably in the range from about 1 nm to about 20 nm. Preferably, the interface state density at the interface between the depinning dielectric layer 30 and the top non-silicon semiconductor layer 22 is less than 5.0×10¹¹ cm⁻² eV⁻¹.

Use of a depinning dielectric layer underneath a gate dielectric layer to depin the Fermi level of a semiconductor channel in a metal oxide semiconductor field effect transistor (MOSFET) is known in the art. Specifically, Lee et al., “Gate stack technology for nanoscale devices,” Materials Today, Vol. 9, No. 6, June 2006, pp. 2-10 shows an example of a depinning dielectric layer employed to enhance performance of GaAs MOSFETs, in which the interface state density is less than 5.0×10¹¹ cm⁻² eV⁻¹. The GaAs channel is located underneath the depinning dielectric layer of Gd₂O₃, which is located underneath a Ga₂O₃ gate dielectric layer. Rajagopalan et al., “1-μm Enhancement Mode GaAs N-Channel MOSFETs With Transconductance Exceeding 250 mS/mm,” IEEE Electron Device Letters, Vol. 28, No. 2, February 2007, pp. 100-102 demonstrates enhancement of electron mobility through the use of a (GdₓGa₁₋ₓ)₂O₃ layer, in which x is about 0.6.

The unpinning properties of the (GdₓGa₁₋ₓ)₂O₃ layer, in which x is in the range from 0 up to and including 1, is advantageously employed in the present invention at the interface between the depinning dielectric layer 30 and the top non-silicon semiconductor layer 22. It is noted that the prior art employs the (GdₓGa₁₋ₓ)₂O₃ layer underneath a gate dielectric, but the (GdₓGa₁₋ₓ)₂O₃ layer does not contact an isolation insulation layer of a semiconductor-on-insulator substrate. In other words, the (GdₓGa₁₋ₓ)₂O₃ layer is employed to unpin the surface states of a semiconductor layer underneath a gate dielectric, but does not concern the unpinning of surface states due to the isolation insulation layer. In the present invention, the (GdₓGa₁₋ₓ)₂O₃ layer is employed between the isolation insulation layer 12 and the top non-silicon semiconductor layer 22 to unpin the surface states due to the isolation insulation layer 12.

Referring to FIG. 2B, the band structure of the inventive hetero-bonded SOI substrate shows valence band energy level Eᵥ and the conduction band energy level E_{c} within various portions of the inventive hetero-bonded SOI substrate. The interface state density at the interface between the depinning dielectric layer 30 and the top non-silicon semiconductor layer 22 is reduced. Specifically, the interface state density at the interface may be less than 5×10¹¹ cm⁻² eV⁻¹. The reduced the interface state density has the advantageous effect of minimizing reduction in the carrier mobility in the top non-silicon semiconductor layer 22 due to the surface states.

As a consequence, the inventive hetero-bonded SOT substrate has an enhanced charge carrier mobility in the top non-silicon semiconductor layer 22 compared to prior art hetero-bonded SOL substrates. The top non-silicon semiconductor layer 22 may be thinned without adversely affecting the carrier mobility in the channel of a MOSFET since the charge carrier mobility in the top non-silicon semiconductor layer 22 is not degraded by the presence of the isolation insulation layer 12 because of the depinning dielectric layer 30. Therefore, the present invention enables an ultra-thin thickness for the top non-silicon semiconductor layer 22, which may be less than 100 nm, and preferably less than 50 nm.

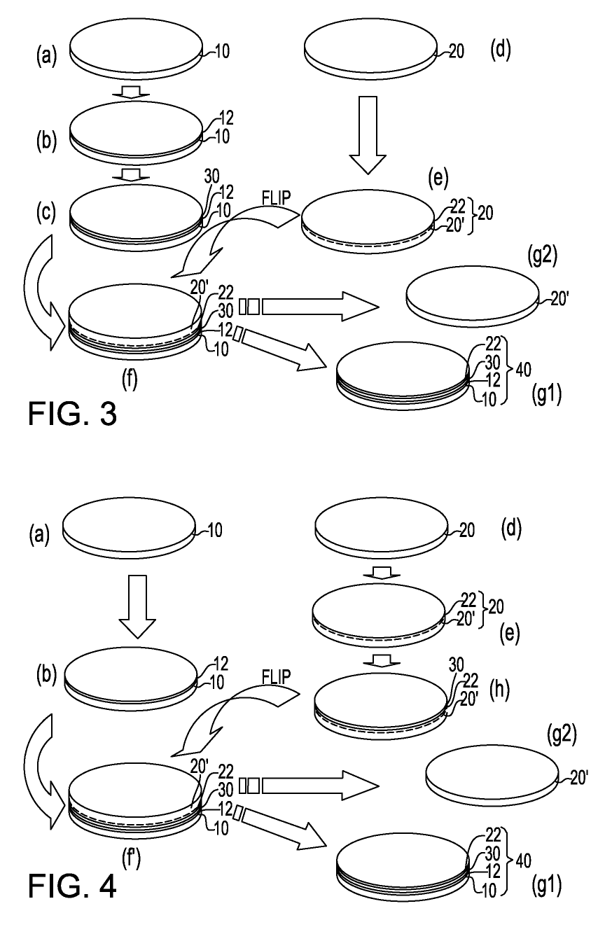

Referring to FIG. 3, a first method of forming the inventive hetero-bonded SOI substrate is shown. In step (a), a semiconductor handle substrate 10 is provided. The composition of the semiconductor handle substrate 10 is as described above. For example, the semiconductor handle substrate 10 may be a silicon substrate.

In step (b), an isolation insulator layer 12 is formed on the semiconductor handle substrate 10. The composition of the isolation insulator layer 12 is as described above. For example, the isolation insulator layer 12 may comprise silicon oxide.

In step (c), a depinning dielectric layer 30 is formed on the isolation insulator layer 12, preferably by deposition. Chemical vapor deposition (CVD) or atomic layer deposition (ALD) may be employed. The properties of the depinning dielectric layer 30 are as described above. For example, the depinning dielectric layer 30 may comprise a (GdₓGa₁₋ₓ)₂O₃ layer, in which the value of x is in the range from 0 up to and including 1. The thickness of the depinning dielectric layer 30 may be in the range from about 0.3 nm to about 100 nm, and preferably in the range from about 1 nm to about 20 nm.

In parallel or in sequence, a non-silicon semiconductor substrate 20 is provided as shown in step (d). The non-silicon semiconductor substrate 20 may comprise any semiconductor material other than pure silicon, including, but not limited to, silicon germanium alloy, silicon carbon alloy, silicon germanium carbon alloy, GaAs, InAs, InP, and other III-V or II-VI compound semiconductors. The non-silicon semiconductor substrate 20 is preferably single crystalline. Hybrid crystal orientations, i.e., multiple crystalline orientations, for the non-silicon semiconductor substrate 20 are explicitly contemplated herein. The semiconductor handle substrate 10 and the non-silicon semiconductor substrate 20 comprise different semiconductor material. For example, the top non-silicon semiconductor substrate 20 may comprise a III-V compound semiconductor layer. In one exemplary embodiment, the III-V compound semiconductor layer may be a GaAs layer.

Referring to step (e), a hydrogen implantation is performed into the non-silicon semiconductor substrate 20 which is provided in step (d). Methods of implanting hydrogen into a semiconductor substrate are well known in the art. A hydrogen implanted layer is formed within the non-silicon semiconductor substrate 20 at a depth at which cleaving is desired subsequent to bonding. In other words, the depth of the hydrogen implantation is substantially the same as the desired thickness of a top non-silicon semiconductor layer to be obtained subsequently. The hydrogen implanted layer divides the non-silicon semiconductor substrate 20 into two parts: a non-silicon semiconductor substrate portion 20′ and a top non-silicon semiconductor layer 22.

Referring to step (f), the non-silicon semiconductor substrate 20 with a hydrogen implanted layer is flipped over and bonded with the semiconductor handle substrate 10 such that a top surface of the depinning dielectric layer 30 is directly bonded to an exposed surface of the non-silicon semiconductor substrate portion 20′. The bonded substrate at this point comprises a stack having the semiconductor handle substrate 10, the isolation insulator layer 12, the depinning dielectric layer 30, the top non-silicon semiconductor layer 22, and the non-silicon semiconductor substrate portion 20′ in that order.

Referring to step (g1), the bonded substrate is subsequently cleaved to provide a hetero-bonded SOI substrate 40, which comprises the semiconductor handle substrate 10, the isolation insulator layer 12, the depinning dielectric layer 30, and the top non-silicon semiconductor layer 22. Concurrently with step (g1), a separated non-silicon semiconductor substrate portion 20′ is obtained in step (g2) by the cleaving of the non-silicon semiconductor substrate portion 20′ from the hetero-bonded SOI substrate 40. Methods cleaving bonded substrates are well known in the art.

Referring to FIG. 4, a second method of forming the inventive hetero-bonded SOI substrate is shown. Steps (a), (b), (d), and (e) according to the first method of forming the inventive hetero-bonded SOI substrate are employed without modification. However, step (c) is omitted in the second method.

Referring to step (h), a depinning dielectric layer 30 is formed on the non-silicon semiconductor substrate 20 with a hydrogen implanted layer. Specifically, the depinning dielectric layer 30 is formed on the top non-silicon semiconductor layer 22, preferably by deposition. The properties of the depinning dielectric layer 30 are as described above. For example, the depinning dielectric layer 30 may comprise a (GdₓGa₁₋ₓ)₂O₃ layer, in which the value of x is in the range from 0 up to and including 1. The thickness of the depinning dielectric layer 30 may be in the range from about 0.3 nm to about 100 nm, and preferably in the range from about 1 nm to about 20 nm.

Referring to step (f′), the non-silicon semiconductor substrate 20 having a hydrogen implanted layer and the depinning dielectric layer 30 is flipped over and bonded with the semiconductor handle substrate 10 such that a top surface of the depinning dielectric layer 30 is directly bonded to an exposed surface of the isolation insulator layer 12. The bonded substrate at this point comprises a stack having the semiconductor handle substrate 10, the isolation insulator layer 12, the depinning dielectric layer 30, the top non-silicon semiconductor layer 22, and the non-silicon semiconductor substrate portion 20′ in that order.

The bonded substrate obtained in step (f′) according to the second method is the same as the bonded substrate obtained in step (f) according to the first method. The bonded substrate obtained in step (f′) is subsequently cleaved to obtain a non-silicon semiconductor substrate portion 20′ and a hetero-bonded SOI substrate 40 in the same manner as in the first method.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A hetero-bonded semiconductor-on-insulator substrate comprising:
a semiconductor handle substrate;
an isolation insulator layer abutting said semiconductor handle substrate;
a depinning dielectric layer abutting said isolation insulator layer; and
a top non-silicon semiconductor layer, wherein said depinning dielectric layer relaxes Fermi level pinning in said top non-silicon semiconductor layer.

2. The hetero-bonded semiconductor-on-insulator substrate of claim 1, wherein an interface state density at an interface between said depinning dielectric layer and said top non-silicon semiconductor layer is less than 5.0×10¹¹ cm² eV⁻¹.

3. The hetero-bonded semiconductor-on-insulator substrate of claim 1, wherein said semiconductor handle substrate comprises a silicon substrate, said isolation insulator layer comprises silicon oxide, and said top non-silicon semiconductor layer comprises a III-V compound layer.

4. The hetero-bonded semiconductor-on-insulator substrate of claim 1, wherein said depinning dielectric layer comprises a (GdₓGa₁₋ₓ)₂O₃ layer and said top non-silicon semiconductor layer comprises a GaAs layer, wherein x is in the range from 0 up to and including 1.

5. The hetero-bonded semiconductor-on-insulator substrate of claim 4, wherein said isolation insulator layer has a thickness in the range from about 10 nm to about 300 nm and said depinning dielectric layer has a thickness in the range from about 0.3 nm to about 100 nm.

6. A method of forming a hetero-bonded semiconductor-on-insulator substrate comprising:
providing a semiconductor handle substrate;
forming an isolation insulator layer on said semiconductor handle substrate;
providing a non-silicon semiconductor substrate having a hydrogen implanted layer;
forming a depinning dielectric layer on a structure selected from said semiconductor handle substrate and said non-silicon semiconductor substrate;
bonding said semiconductor handle substrate and said non-silicon semiconductor substrate, wherein said depinning dielectric layer abuts a bonding surface; and
cleaving said non-silicon semiconductor substrate along said hydrogen implanted layer.

7. The method of claim 6, wherein an interface state density at an interface between said depinning dielectric layer and said top non-silicon semiconductor layer is less than 5.0×10¹¹ cm⁻² eV⁻¹.

8. The method of claim 6, wherein said semiconductor handle substrate comprises a silicon substrate, said isolation insulator layer comprises silicon oxide, and said top non-silicon semiconductor layer comprises a III-V compound layer.

9. The method of claim 6, wherein said depinning dielectric layer comprises a (GdₓGa₁₋ₓ)₂O₃ layer and said top non-silicon semiconductor layer comprises a GaAs layer, wherein x is in the range from 0 up to and including 1.
